(19) United States
(12) Patent Application Publication
(10) Pub. No.: US 2022/0075755 A1
(43) Pub. Date: Mar. 10, 2022

(54) METHOD FOR FORMING DATABASE FOR MEMORY TEST AND METHOD FOR TESTING MEMORY

(71) Applicant: CHANGXIN MEMORY TECHNOLOGIES,INC., Hefei City (CN)

(72) Inventor: Yangyang DAI, Hefei City (CN)

(21) Appl. No.: 17/455,339

(22) Filed: Nov. 17, 2021

Related U.S. Application Data
(63) Continuation of application No. PCT/CN2021/079978, filed on Mar. 10, 2021.

(30) Foreign Application Priority Data
Mar. 27, 2020 (CN) 202010229170.2

(51) Int. Cl. G06F 16/11

(52) U.S. Cl. CPC G06F 16/11

(57) ABSTRACT

The present application provides a method for forming a database for memory test and a method for testing a memory. The method includes: testing the memory multiple times at a set timestep taking a preset time value as a starting point under a memory parameter, a result including passed or failed; taking, as a subgroup, the testing results in which consecutive tests are passed under the memory parameter, the testing results being capable of forming at least one subgroup; taking the subgroup with the largest number of testing results as a calibration group, and acquiring a selected time value within a testing time range of the calibration group; taking a difference between the selected time value and the preset time value as a deviation value between a data strobe signal and a clock signal, which corresponds to the memory parameter; and changing the memory parameter and repeating the above steps.

### CROSS-REFERENCE TO RELATED APPLICATIONS

This application is a continuation application of International Patent Application No. PCT/CN2021/079978, filed on Mar. 10, 2021, which claims priority to Chinese Patent Application No. 202010229170.2, filed with the Chinese Patent Office on Mar. 27, 2020 and entitled “METHOD FOR FORMING DATABASE FOR MEMORY TES AND METHOD FOR TESTING MEMORY”. International Patent Application No. PCT/CN2021/079978 and Chinese Patent Application No. 202010229170.2 are incorporated herein by reference in their entireties.

### TECHNICAL FIELD

The present application relates to the field of memory testing, and in particular to a method for forming a database for memory test and a method for testing a memory.

### BACKGROUND

Upon testing a memory, the memory can generate a valid data window based on an external clock signal, and a testing device for the memory acquires data for testing.

Some testing devices can automatically track a data strobe signal (DQS) to acquire data for testing, while some testing devices do not have an automatic tracking function. As the operating speed of the memory increases, the data window of the memory will be shifted, the testing devices without the automatic tracking function cannot correctly capture valid data which the shifted data window has, and thus cannot accurately acquire data, which causes an inaccurate testing for the memory.

Therefore, it is an urgent problem to improve accuracy of a testing device without an automatic tracking function.

### SUMMARY

The technical problem to be solved by the present application is to provide a method for forming a database for memory test and a method for testing a memory, which can improve accuracy of a testing device without an automatic tracking function.

In order to solve the above-mentioned problem, the present application provides a method for forming a database for memory test, including steps of: testing the memory multiple times at a set timestep taking a preset time value as a starting point under a memory parameter, the testing result including passed and failed; taking, as a subgroup, the testing results in which consecutive tests are passed under the memory parameter, the testing results being capable of forming at least one subgroup; taking the subgroup with the largest number of testing results as a calibration group, and acquiring a selected time value within a testing time range of the calibration group; taking a difference between the selected time value and the preset time value as a deviation value between a data strobe signal and a clock signal, which corresponds to the memory parameter; and changing the memory parameter and repeating the above steps to form the database, the database including the deviation value between the data strobe signal and the clock signal and a corresponding relationship between the deviation value and the memory parameter.

Further, the step of acquiring the selected time value within the testing time range of the calibration group may further include: acquiring a testing time value corresponding to the first passed testing result of the calibration group as an initial time value; acquiring a testing time value corresponding to the first failed testing result after the calibration group as a final time value; and taking a fraction of the difference between the final time value and the initial time value as a parameter, and taking the sum of the initial time value and the parameter as the selected time value.

Further, one half of the difference between the final time value and the initial time value may be taken as the parameter.

Further, taking the subgroup with the largest number of testing results as the calibration group may include steps of: acquiring an n^{th} subgroup; acquiring an (n+1)^{th} subgroup; comparing the number of testing results of the n^{th} subgroup with the number of testing results of the (n+1) subgroup, if the number of testing results of the n^{th} subgroup is greater than the number of testing results of the (n+1)^{th} subgroup, the number of testing results of the n^{th} subgroup is taken as the number of current testing results, and if the number of testing results of the n^{th} subgroup is less than the number of testing results of the (n+1)^{th} subgroup, the number of testing results of the (n+1)^{th} subgroup is taken as the number of current testing results; acquiring an (n+2)^{th} subgroup; comparing the number of testing results of the (n+2)^{th} subgroup with the number of current testing results, if the number of testing results of the (n+2)^{th} subgroup is greater than the number of current testing results, the number of testing results of the (n+2)^{th} subgroup is taken as the number of current testing results, and if the number of testing results of the (n+2)^{th} subgroup is less than the number of current testing results, the number of current testing results is maintained; and repeating the above steps until the subgroup with the largest number of testing results within a preset time range is obtained.

Further, the preset time value may be a time value at which a read delay elapses.

Further, testing data may be compared with preset testing data to determine whether the testing results are passed.

Further, a change trend of the testing results may follow the order of: failed, passed, and failed.

Further, the memory may be tested at the preset time value, and the testing result may be failed.

Further, the memory parameter may include at least voltage and temperature.

The present application further provides a method for testing a memory, including steps of: providing a database, the database including a deviation value between a data strobe signal and a clock signal and a corresponding relationship between the deviation value and a memory parameter, and the database being formed by the method according to claim 1; searching the database for a deviation value corresponding to a preset memory parameter when the memory needs to be tested under the preset memory parameter; acquiring a time value at which testing is to be performed according to the deviation value; and testing the memory at the time value.

Further, the step of acquiring the time value at which the testing is to be performed according to the deviation value may further include: taking the sum of the deviation value and the time value at which a read delay elapses as the time value at which the testing is to be performed.

The advantages of the present application lie in that when the testing device tests the memory, a boundary line between the area where the testing results are passed and the area where the testing results are failed is not smooth, which may lead to an inaccurate deviation value tDQSCK acquired by the testing device. For example, after one testing result is passed, the next testing result may be failed. Therefore, the boundary line between the area of passed testing results and the area of failed testing results is not smooth, which in turn affects the testing device to perform the test, while the method for forming a database for memory test according to the present application can acquire the deviation value tDQSCK within the maximum area of passed testing results, thereby avoiding the inaccuracy caused by the non-smooth boundary line.

Another advantage of the present application is that the time value at which the testing is to be performed on the memory may be determined directly based on the records of the database, and the testing device tests the memory at the time value, so that the testing device without an automatic tracking function can also accurately obtain testing data.

### BRIEF DESCRIPTION OF DRAWINGS

To describe the technical solutions in the embodiments of the present application more clearly, the following briefly introduces the accompanying drawings required for describing the embodiments of the present application. Apparently, the accompanying drawings in the following description show merely some embodiments of the present application, and those of ordinary skill in the art may still derive other drawings from these accompanying drawings without creative efforts.

FIG. 1 is a schematic diagram showing the steps in one embodiment of the method for forming a database for memory test according to the present application;

FIG. 2 is a timing diagram after a read command is applied to a memory device;

FIG. 3 is a schematic structural diagram of a testing device testing the memory;

FIG. 4 is a plot showing shmoo profile of the testing results under constant temperature, wherein the ordinate is the voltage V, and the abscissa is a deviation value tDQSCK between a data strobe signal and a clock signal;

FIG. 5 is a profile that separately lists the distribution of passed testing results and failed testing results under voltage V1 in FIG. 4; and

FIG. 6 is a schematic diagram showing the steps in one embodiment of the method for testing a memory according to the present application.

### DESCRIPTION OF EMBODIMENTS

In order to make the objective, technical means and effects of the present application more clearly, the present application will be further elaborated below with reference to the accompanying drawings. It should be understood that the embodiments described here are merely some embodiments, rather than all embodiments, of the present application, are not intended to limit the present application. Based on the embodiments of the present application, all other embodiments derived by those of ordinary skill in the art without creative efforts shall fall within the scope of protection of the present application.

The objective of the method for forming a database for memory test according to the present application is to form the database, the database includes a deviation value tDQSCK between a data strobe signal DQS and a clock signal CK and a corresponding relationship between the deviation value tDQSCK and a memory parameter. The deviation value tDQSCK between the data strobe signal DQS and the clock signal CK is the timing from the read delay elapsed to the actual valid DQS/DQ output, which is a conventional parameter of a semiconductor. The memory parameter refers to a parameter that affects the performance of the memory, which includes at least voltage and temperature. The deviation value tDQSCK may be different under different voltages and temperatures.

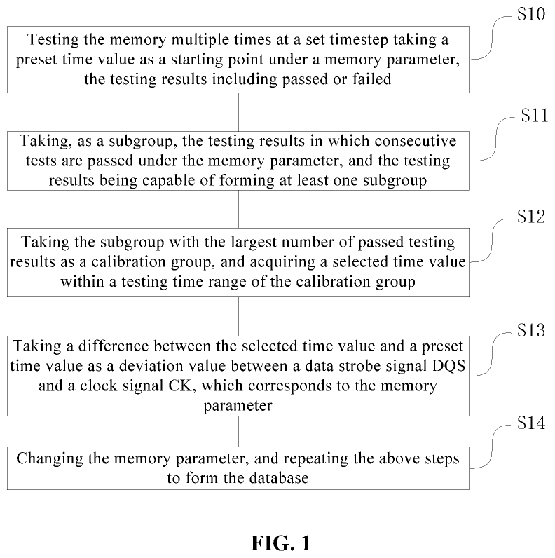

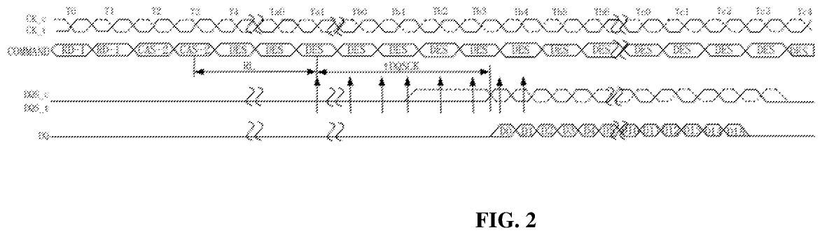

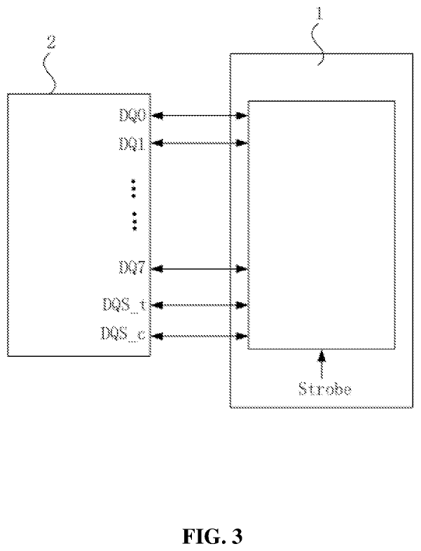

FIG. 1 is a schematic diagram showing the steps in one embodiment of the method for forming a database for memory test according to the present application, FIG. 2 is a timing diagram after a read command is applied to a memory device, and FIG. 3 is a schematic structural diagram of a testing device testing the memory. Referring to FIGS. 1, 2 and 3, when forming the database, it is necessary to adopt a testing device 1 to test a memory 2 and obtain testing results. Specifically, the method for forming a database for memory test includes steps S10, S11, S12, S13 and S14.

In step S10, the memory is tested multiple times at a set timestep taking a preset time value as a starting point under a memory parameter, the testing results may include passed or failed.

The memory parameter includes at least voltage and temperature. In this embodiment, the memory parameter is voltage V and temperature T, for example, voltage V1, V2, and temperature T1, T2. The memory parameter described in this step S10 refers to a combination of voltage V and temperature T, for example, the memory parameter is a combination of voltage V1 and temperature T1, a combination of voltage V1 and temperature T2, a combination of voltage V2 and temperature T1, and a combination of voltage V2 and temperature T2. The step S10 may be a step of applying a read command to a memory under voltage V1 and temperature T1.

In this embodiment, the preset time value is a time value RL at which a read delay elapses, the testing device 1 tests the memory multiple times at a set timestep taking the time value RL at which the read delay elapses as a starting point, and the positions at which the testing device tests the memory are indicated by the arrows as shown in FIG. 2. The set timestep may be selected according to actual requirements, such as several nanoseconds or ten and several nanoseconds. For example, the testing device tests the memory one time every 5 nanoseconds taking the time value RL at which the read delay elapses as the starting point, and obtains testing results which are passed or failed.

Further, in this embodiment, the testing device 1 provides a strobe signal Strobe, and the testing device 1 tests the memory 2 according to the strobe signal Strobe. The strobe signal Strobe may be a timing signal.

The testing device tests the memory at different testing times, and the testing results may be passed or failed. Testing data may be compared with preset testing data to determine whether the testing results are passed. If the difference between the testing data and the preset testing data is within a set error range, the testing result is passed. If the difference between the testing data and the preset testing data is beyond the set error range, the testing result is failed, and is expressed by shading in the shmoo profile shown in FIG. 4.

Further, the testing device may carry out tests on the memory by writing the testing data into the memory and reading the testing data.

Further, the testing device stops testing the memory one-clock period after an actual valid DQS/DQ is output. For example, as shown in FIG. 2, the testing device tests the memory between the clock period Tal and the clock period Tb4, and the testing device stops testing the memory before the next valid DQS/DQ is output.

FIG. 4 is a plot showing shmoo profile of the testing results under constant temperature, wherein the ordinate is the voltage V, and the abscissa is a deviation value tDQSCK between a data strobe signal DQS and a clock signal CK. In FIG. 4, the area of failed testing results is expressed by shading. Referring to FIGS. 2 and 4, under constant voltage V, such as voltage V1, the testing result may be passed or failed as the deviation value tDQSCK changes.

In order to achieve the objective of the present application and improve the accuracy of data collection of the database, the selection of testing time in the present application needs to meet the following conditions: after the preset time value, the change trend of the testing results may follow the order of: failed, passed, and failed. In other words, the testing result of the testing carried out at the preset time value is failed, and the testing result becomes passed after several preset timesteps have elapsed, and the testing result becomes failed after several preset timesteps have further elapsed.

In step S11, the testing results in which consecutive tests are passed under the memory parameter are taken as a subgroup, and the testing results can form at least one subgroup.

Referring to FIG. 4, in this step, as the deviation value tDQSCK changes, the testing result is converted from failed to passed. If one passed testing result is followed by a failed testing result, the one passed testing result is taken as a subgroup, and if four consecutive passed testing results are followed by a failed testing result, the four consecutive passed testing results are taken as a subgroup.

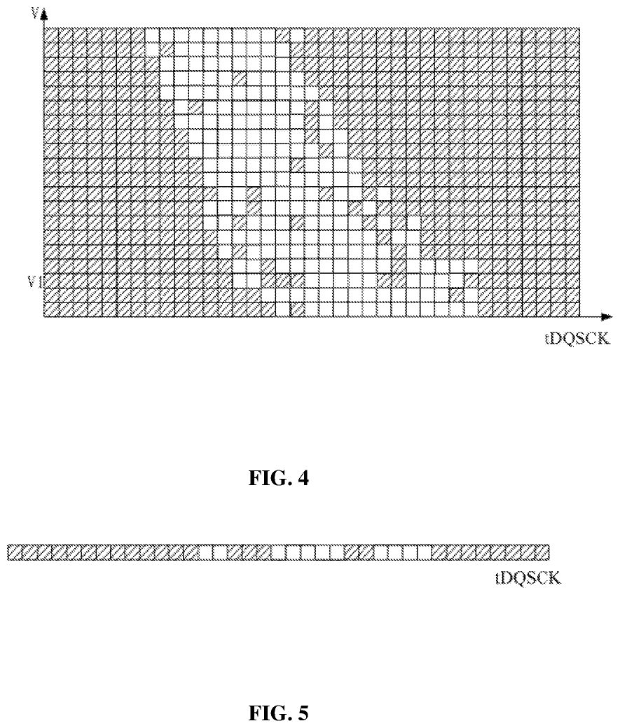

For example, the distribution of passed testing results and failed testing results under voltage V1 in FIG. 4 is listed separately. Referring to FIG. 5, in the initial stage, the testing results are failed, two consecutive testing results are passed as the tDQSCK changes, and thus the two consecutive testing results are defined as a subgroup 1; after the subgroup 1, the testing results become failed; and then the testing results become passed again as the tDQSCK changes, and specifically, five consecutive testing results are passed, and thus the five testing results are defined as a subgroup 2; after the subgroup 2, the testing results become failed, and then the testing results become passed again as the tDQSCK changes, and specifically, four consecutive testing results are passed, and thus the four testing results are defined as a subgroup 3, and from then the testing results are always failed.

In step S12, a subgroup with the largest number of passed testing results is taken as a calibration group, and a selected time value is acquired within a testing time range of the calibration group.

The present application enumerates a method for acquiring a calibration group: acquiring an n^{th} subgroup; acquiring an (n+1)^{th} subgroup; comparing the number of passed testing results of the n^{th} subgroup with the number of passed testing results of the (n+1) subgroup, if the number of passed testing results of the n^{th} subgroup is greater than the number of passed testing results of the (n+1)^{th} subgroup, the number of passed testing results of the n^{th} subgroup is taken as the number of current passed testing results, and if the number of passed testing results of the n^{th} subgroup is less than the number of passed testing results of the (n+1)^{th} subgroup, the number of passed testing results of the (n+1)^{th} subgroup is taken as the number of current passed testing results; acquiring an (n+2)^{th} subgroup; comparing the number of passed testing results of the (n+2)^{th} subgroup with the number of current passed testing results, if the number of passed testing results of the (n+2)^{th} subgroup is greater than the number of current passed testing results, the number of passed testing results of the (n+2)^{th} subgroup is taken as the number of current passed testing results, and if the number of passed testing results of the (n+2)^{th} subgroup is less than the number of current passed testing results, the number of current passed testing results is maintained; and repeating the above steps until the subgroup with the largest number of passed testing results within a preset time range is obtained.

For example, as shown in FIG. 5, the distribution of passed testing results and failed testing results under voltage V1 is taken as an example.

A subgroup 1 and a subgroup 2 are acquired.

The number of passed testing results of the subgroup 1 is compared with the number of passed testing results of the subgroup 2. In this embodiment, the number of passed testing results of the subgroup 1 is 2, and the number of passed testing results of the subgroup 2 is 5, the number of passed testing results of the subgroup 1 is less than the number of passed testing results of the subgroup 2, and thus the number of passed testing results of the subgroup 2 is taken as the number of current passed testing results, that is, the number of current passed testing results is 5.

A subgroup 3 is acquired.

The number of passed testing results of the subgroup 3 is compared with the number of current passed testing results. In this embodiment, the number of passed testing results of the subgroup 3 is 4, which is less than the number of current passed testing results, and thus the number of passed testing results of the subgroup 2 is taken as the number of current passed testing results, and subsequent testing results are all failed, and thus the subgroup 2 is the subgroup with the largest number of passed testing results within the preset time range, that is, the calibration group.

In step S12, the testing device is further required to acquire a selected time value within a testing time range of the calibration group.

In this step, any time value within the testing time range of the calibration group may be selected as the selected time value.

Further, in order to improve the accuracy of the database, the step of acquiring the selected time value within the testing time range of the calibration group further includes: acquiring a testing time value corresponding to the first passed testing result of the calibration group as an initial time value; acquiring a testing time value corresponding to the first failed testing result after the calibration group as a final time value; and taking a fraction of the difference between the final time value and the initial time value as a parameter, and taking the sum of the initial time value and the parameter as the selected time value. Further, one half of the difference between the final time value and the initial time value is taken as the parameter, and the sum of the initial time value and the parameter is taken as the selected time value.

For example, in this embodiment, a testing time value corresponding to the first passed testing result of the subgroup 2 is acquired as an initial time value; a testing time value corresponding to the first failed testing result after the subgroup 2 is taken as a final time value; one half of the difference between the final time value and the initial time value is taken as the parameter, and the sum of the initial time value and the parameter is taken as the selected time value.

In step S13, a difference between the selected time value and the preset time value is taken as a deviation value between a data strobe signal DQS and a clock signal CK, which corresponds to the memory parameter.

The testing result of the testing carried out at the selected time value must be passed, and thus the difference between the selected time value and the preset time value may be taken as the deviation value tDQSCK between the data strobe signal DQS and the clock signal CK, which corresponds to the memory parameter.

In step S14, the memory parameter is changed, and the above steps are repeated to form the database.

For example, the memory parameter is changed to be the combination of voltage V2 and temperature T1, and steps S10 to S13 are repeated to acquire the deviation value between the data strobe signal and the clock signal, which corresponds to the memory parameter. By analogy, the database is formed.

The database includes the deviation value tDQSCK between the data strobe signal DQS and the clock signal CK and the corresponding relationship between the deviation value tDQSCK and the memory parameter. The database may be stored in the testing device.

Further, a voltage may be selected to obtain the deviation value corresponding to the memory parameter; another voltage may be selected to obtain the deviation value corresponding to another memory parameter, and by analogy, the deviation values corresponding to multiple memory parameters may be selected, and the multiple deviation values may be stored in the database in the form of a curve.

A boundary line between the area of passed testing results and the area of failed testing results is not smooth, as shown in FIG. 4 and FIG. 5, which may lead to an inaccurate deviation value tDQSCK acquired by the testing device. For example, one passed testing result is followed by a failed testing result. Therefore, the boundary line between the area of passed testing results and the area of failed testing results is not smooth, which in turn affects the testing by the testing device, while the method for forming a database for memory test according to the present application can acquire the deviation value tDQSCK within the maximum area of passed testing results, thereby avoiding the inaccuracy caused by the non-smooth boundary line.

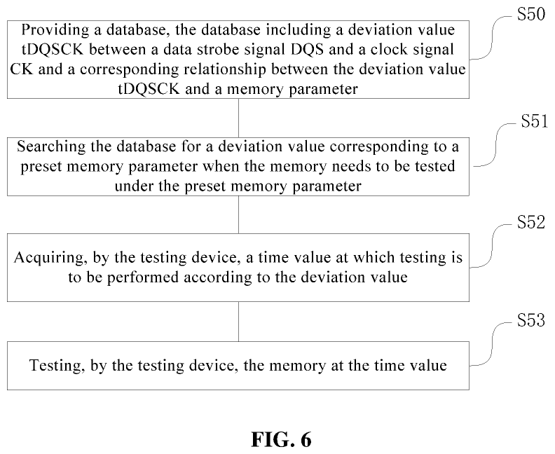

The present application further provides a method for testing a memory. Referring to FIG. 6, which is a schematic diagram showing the steps of the method for testing a memory according to the present application. The method for testing a memory includes steps S50, SM, S52 and S53.

In step S50, a database is provided, the database including a deviation value tDQSCK between a data strobe signal DQS and a clock signal CK and a corresponding relationship between the deviation value tDQSCK and a memory parameter.

The database is formed by the above-described method for forming a database.

In step S51, the database is searched for a deviation value corresponding to a preset memory parameter when the memory needs to be tested under the preset memory parameter.

The preset memory parameter includes at least voltage V and temperature T. For example, the database is searched for a deviation value tDQSCK corresponding to the combination of voltage V1 and temperature T1 when the memory needs to be tested under voltage V1 and temperature T1.

In step S52, the testing device acquires a time value at which the testing is to be performed according to the deviation value.

In this step, the sum of the deviation value and a time value at which a read delay elapses is taken as a time value at which the testing is to be performed. That is, the time when the testing device tests the memory is determined.

In step S53, the testing device tests the memory at the time value.

With respect to the method for testing a memory according to the present application, the time value at which the testing is to be performed on the memory may be determined directly based on the records of the database, and the testing device tests the memory at the time value, so that the testing device without the automatic tracking function can also accurately obtain testing data.

The foregoing descriptions are only the preferred embodiments of the present application. It should be noted that, several improvements and modifications can be made by those of ordinary skill in the art without departing from the principle of the present application, and these improvements and modifications should also be considered within the scope of protection of the present application.

What is claimed is:

1. A method for forming a database for memory test, comprising steps of:
testing memory multiple times at a set timestep taking a preset time value as a starting point under a memory parameter, a testing result comprising passed or failed;
taking, as a subgroup, the testing results in which consecutive tests are passed under the memory parameter, the testing results being capable of forming at least one subgroup;
taking the subgroup with the largest number of testing results as a calibration group, and acquiring a selected time value within a testing time range of the calibration group;
taking a difference between the selected time value and the preset time value as a deviation value between a data strobe signal and a clock signal, which corresponds to the memory parameter; and
changing the memory parameter and repeating the above steps to form the database, the database including the deviation value between the data strobe signal and the clock signal and a corresponding relationship between the deviation value and the memory parameter.

2. The method for forming a database for memory test according to claim 1, wherein the step of acquiring the selected time value within the testing time range of the calibration group further comprises:
acquiring a testing time value corresponding to a first passed testing result of the calibration group as an initial time value;
acquiring a testing time value corresponding to a first failed testing result after the calibration group as a final time value; and
taking a fraction of the difference between the final time value and the initial time value as a parameter, and taking a sum of the initial time value and the parameter as the selected time value.

3. The method for forming a database for memory test according to claim 2, wherein one half of the difference between the final time value and the initial time value is taken as the parameter.

4. The method for forming a database for memory test according to claim 1, wherein taking the subgroup with the largest number of testing results as the calibration group comprises steps of:
acquiring an n^{th} subgroup;
acquiring an (n+1)^{th} subgroup;
comparing the number of testing results of the n^{th} subgroup with the number of testing results of the (n+1) subgroup, if the number of testing results of the n^{th} subgroup is greater than the number of testing results of the (n+1)^{th} subgroup, the number of testing results of the n^{th} subgroup is taken as the number of current testing results, and if the number of testing results of the n^{th} subgroup is less than the number of testing results of the (n+1)^{th} subgroup, the number of testing results of the (n+1)^{th} subgroup is taken as the number of current testing results;
acquiring an (n+2)^{th} subgroup;
comparing the number of testing results of the (n+2)^{th} subgroup with the number of current testing results, if the number of testing results of the (n+2)^{th} subgroup is greater than the number of current testing results, the number of testing results of the (n+2)^{th} subgroup is taken as the number of current testing results, and if the number of testing results of the (n+2)^{th} subgroup is less than the number of current testing results, the number of current testing results is maintained; and
repeating the above steps until the subgroup with the largest number of testing results within a preset time range is obtained.

5. The method for forming a database for memory test according to claim 1, wherein the preset time value is a time value at which a read delay elapses.

6. The method for forming a database for memory test according to claim 1, wherein testing data is compared with preset testing data to determine whether the testing results are passed.

7. The method for forming a database for memory test according to claim 1, wherein a change trend of the testing results follows the order of: failed, passed, and failed.

8. The method for forming a database for memory test according to claim 7, wherein the memory is tested at the preset time value, and the testing result is failed.

9. The method for forming a database for memory test according to claim 1, wherein the memory parameter includes at least voltage and temperature.

10. A method for testing a memory, comprising steps of:
providing a database, the database comprising a deviation value between a data strobe signal and a clock signal and a corresponding relationship between the deviation value and a memory parameter, and the database being formed by the method according to claim 1;
searching the database for a deviation value corresponding to a preset memory parameter when the memory needs to be tested under the preset memory parameter;
acquiring a time value at which testing is to be performed according to the deviation value; and
testing the memory at the time value.

11. The method for testing a memory according to claim 10, wherein the step of acquiring the time value at which the testing is to be performed according to the deviation value further comprises: taking a sum of the deviation value and the time value at which a read delay elapses as the time value at which the testing is to be performed.
